(19) United States
(12) Patent Application Publication
(10) Pub. No.: US 2013/0340679 A1
(43) Pub. Date: Dec. 26, 2013

(54) VACUUM DEPOSITION DEVICE

(71) Applicants: Nobuyuki Miyagawa, Osaka (JP); Taisuke Nishimori, Osaka (JP); Takashi Anjiki, Osaka (JP)

(72) Inventors: Nobuyuki Miyagawa, Osaka (JP); Taisuke Nishimori, Osaka (JP); Takashi Anjiki, Osaka (JP)

(73) Assignee: PANASONIC CORPORATION, Osaka (JP)

(21) Appl. No.: 14/003,878

(22) PCT Filed: Mar. 12, 2012
(86) PCT No.: PCT/JP2012/056256

§ 371 Date: Sep. 9, 2013

(30) Foreign Application Priority Data
Mar. 16, 2011 (JP) 2011-058303

(51) Int. Cl. C23C 16/52

(52) U.S. Cl. CPC C23C 16/52
USPC 118/712

(57) ABSTRACT

The present invention provides a vacuum deposition device that can improve the measurement accuracy of the thickness of the deposition film. The vacuum deposition device includes, in a vacuum chamber, a plurality of evaporation sections, a deposition target, a tubular body surrounding a space between the plurality of evaporation sections and the deposition target, and a film thickness meter. Deposition material vaporized from the plurality of evaporation sections passes through tubular body, reaches a surface of the deposition target, and is deposited on surface. Between film thickness meter and at least one of the evaporation sections, a guide tube is disposed which guides deposition material vaporized from the evaporation section to film thickness meter. An opening surface of the guide tube on the evaporation section side is disposed at substantially the same level as that of the opening surface of the evaporation section or inside the evaporation section.

### TECHNICAL FIELD

The present invention relates to a vacuum deposition device that vaporizes a deposition material in a vacuum atmosphere and deposits the vaporized deposition material on a deposition target.

### BACKGROUND ART

In a vacuum deposition device, an evaporation section and deposition target are disposed in a vacuum chamber, and a deposition material is vaporized and is deposited on the deposition target in a state where pressure in the vacuum chamber is reduced. In this case, the evaporation section is heated and the deposition material stored in the evaporation section is molten and evaporated, or the deposition material is vaporized by sublimation or the like and the vaporized deposition material is accumulated and deposited on a surface of the deposition target.

In such vacuum deposition, the mean free path of the deposition material vaporized from the evaporation section is extremely long, and the vaporized deposition material travels rectilinearly in the vacuum chamber. However, the whole deposition material does not travel to the deposition target. In other words, the whole deposition material does not adhere to a surface of the deposition target, and hence the use efficiency of the deposition material can decrease or the deposition rate can decrease.

Therefore, the following vacuum deposition device is disclosed (for example, Patent literature 1):
a tubular body surrounds the space where an evaporation section and deposition target disposed in the vacuum chamber are faced to each other, and the material vaporized from the evaporation section by heating of the tubular body is deposited on the surface of the deposition target through the tubular body. Thus, a method of reducing the decrease in use efficiency of the deposition material and decrease in deposition rate by surrounding the space having the evaporation section and deposition target with the tubular body is known.

In order to produce a light emission layer and carrier transportation layer and the like of an organic electroluminescence (EL) element, a plurality of deposition materials are required to be co-deposited. In this case, a method of using a plurality of evaporation sections and depositing a plurality of vaporized materials on a deposition target in a mixed state of the materials is also disclosed (for example, Patent literature 2). Also in this case, the space having the plurality of evaporation sections and the deposition target is surrounded with a tubular body, so that the decrease in use efficiency of the deposition materials and decrease in deposition rate are reduced.

When a plurality of vaporized materials are co-deposited as discussed above, the deposition rate of each deposition material is required to be controlled so as to deposit the plurality of deposition materials on the surface of the deposition target at a determined mixing ratio. Therefore, a film thickness meter is disposed near each deposition material, the deposition rate of each deposition material is measured, the heating temperature of the heater of each evaporation section is feedback-controlled, and the deposition rate of each deposition material is adjusted so as to correspond to the determined mixing ratio.

### PRIOR ART DOCUMENTS

### Patent Literature

Patent literature 1 Japanese Unexamined Application Publication No. 09-272703
Patent literature 2: Japanese Unexamined Application Publication No. 2004-59982

### SUMMARY OF THE INVENTION

### Problems to be Resolved by the Invention

In the above-mentioned method, however, vaporized deposition materials are mixed by reflection or re-evaporation on the inner surface of a tubular body. Therefore, to a film thickness meter for measuring the thickness of a deposition film of a certain deposition material, another deposition material that is not concerned can adhere. There is a possibility of disturbing correct measurement of the deposition rate by the film thickness meter and correct feedback control in a heater and fluctuating the deposition rate. Especially, when the mixing ratio of the deposition material whose film thickness is to be measured to all the deposition materials is low, namely several percentages or lower, the influence of the adhesion of another deposition material whose film thickness is not to be measured can become remarkable and correct film thickness measurement can become difficult.

The present invention addresses such a problem. The present invention provides a vacuum deposition device that can inhibit a deposition material other than the deposition material whose film thickness is to be measured from adhering to the film thickness meter during deposition of the deposition material and can improve the measurement accuracy of the thickness of the deposition film.

### Means of Solving the Problems

A vacuum deposition device of the present invention includes, in a vacuum chamber, a plurality of evaporation sections, a deposition target, a tubular body surrounding a space between the plurality of evaporation sections and the deposition target, and a film thickness meter. In the vacuum deposition device, a deposition material vaporized from the plurality of evaporation sections passes through the tubular body, reaches a surface of the deposition target, and is deposited on the surface. Between the film thickness meter and at least one of the plurality of evaporation sections, a guide tube is disposed which guides the deposition material vaporized from the evaporation section to the film thickness meter. An opening surface of the guide tube on the evaporation section side is disposed at substantially the same level as that of the opening surface of the evaporation section or inside the evaporation section.

In the present invention, preferably, the guide tube is extended to the inside of the evaporation section, and the length of a part of the guide tube inside the evaporation section is two or more times the square root of the area of the opening surface of the evaporation section.

In the present invention, at least one of the plurality of evaporation sections includes a lid body disposed at substantially the same level as that of the opening surface of the evaporation section or inside the evaporation section so as to block the opening of the evaporation section. The lid body includes the following elements:
an orifice for deposition for guiding, into the tubular body, the deposition material vaporized from the evaporation section having the lid body; and
an orifice for film thickness measurement for guiding, to the film thickness meter, the deposition material vaporized from the evaporation section having the lid body.
   Preferably, the guide tube is disposed between the film thickness meter and the orifice for film thickness measurement.

Preferably, an opening area controlling means for allowing the opening area of the orifice for deposition to be adjusted is disposed on the lid body.

Preferably, an opening area controlling means for allowing the opening area of the orifice for film thickness measurement to be adjusted is disposed on the lid body.

In the present invention, preferably, a heating mechanism is disposed in at least one of the lid body and the guide tube, and a temperature adjusting mechanism for controlling the heating mechanism is provided.

### Effect of the Invention

The vacuum deposition device of the present invention can inhibit a deposition material other than the deposition material whose film thickness is to be measured from adhering to the film thickness meter during deposition of the deposition material, and hence can improve the measurement accuracy of the thickness of the deposition film.

### BRIEF DESCRIPTION OF DRAWINGS

FIG. 1 is a schematic sectional view showing an example of an embodiment of a vacuum deposition device of the present invention.

FIG. 2 is a partially enlarged schematic sectional view showing an example of another embodiment of the vacuum deposition device.

FIG. 3 is a schematic sectional view showing an example of yet another embodiment of the vacuum deposition device.

FIG. 4 is a partially enlarged schematic sectional view showing an example of still another embodiment of the vacuum deposition device.

FIG. 5 is a plan view showing an example of an embodiment of an opening area controlling means disposed in an orifice for deposition in the vacuum deposition device.

FIG. 6 is a plan view showing an example of another embodiment of the opening area controlling means disposed in the orifice for deposition in the vacuum deposition device.

FIG. 7 is a plan view showing an example of yet another embodiment of the opening area controlling means disposed in the orifice for deposition in the vacuum deposition device.

FIG. 8 is a plan view showing an example of an embodiment of an opening area controlling means disposed in an orifice for film thickness measurement in the vacuum deposition device.

FIG. 9 is a plan view showing an example of another embodiment of the opening area controlling means disposed in the orifice for film thickness measurement in the vacuum deposition device.

FIG. 10 is a plan view showing an example of yet another embodiment of the opening area controlling means disposed in the orifice for film thickness measurement in the vacuum deposition device.

FIG. 11 is a schematic sectional view showing an example of another embodiment of the vacuum deposition device of the present invention.

FIG. 12 shows a simulation result of a deposition rate when deposition is performed using the vacuum deposition device in the embodiment of the present invention.

FIG. 13 shows another simulation result of the deposition rate.

FIG. 14 shows the relationship between the deposition rate and the diameter of the orifice for film thickness measurement in the simulation result.

### DESCRIPTION OF EMBODIMENTS

An exemplary embodiment of the present invention is described hereinafter.

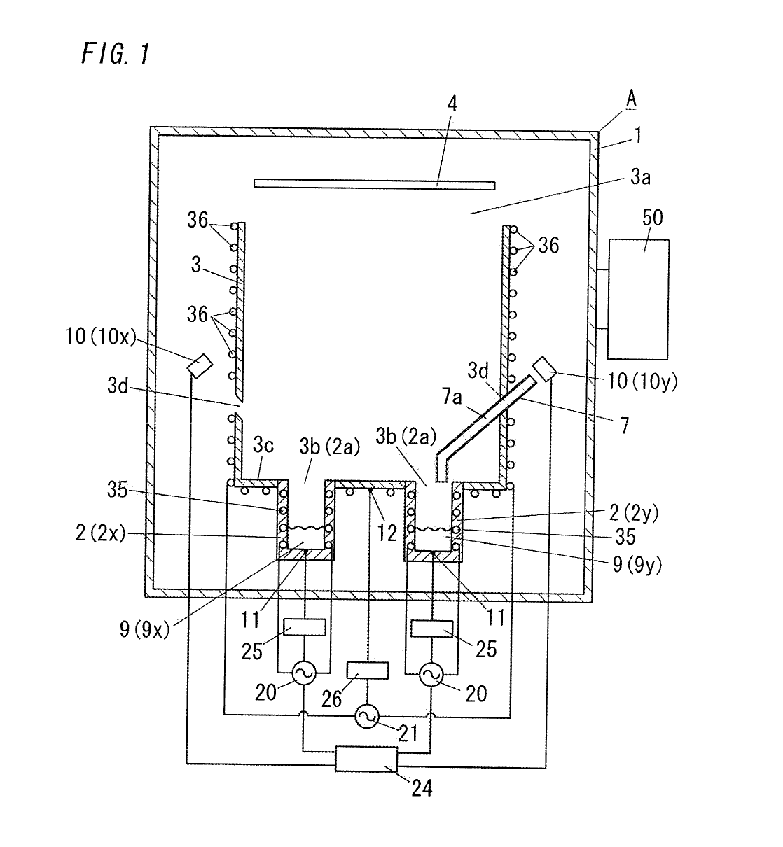

FIG. 1 shows an example of an exemplary embodiment of a vacuum deposition device A in the present invention. In the vacuum deposition device of the present invention, the inside of a vacuum chamber 1 can be decompressed into the vacuum state by exhaust using a vacuum pump 50.

A tubular body 3 is disposed in the vacuum chamber 1. The tubular body 3 is formed of a closed-end square cylinder or circular cylinder, and an opening is formed as a tubular body opening 3a in the upper surface of the tubular body 3. A deposition target 4 of a substrate shape is disposed above the tubular body opening 3a such that the lower surface of the deposition target 4 faces the tubular body opening 3a. The deposition target 4 is not limited especially, and can be formed of a glass substrate or the like.

A tubular body heater 36 is wound on the outer periphery of the tubular body 3. The tubular body 3 can be heated by heating the tubular body heater 36 by power fed from a power supply 21 for tubular body heater that is connected to the tubular body heater 36. The power supply 21 for tubular body heater is disposed outside the vacuum chamber 1.

The tubular body 3 includes a temperature measuring means 12 for tubular body such as a thermocouple capable of measuring a temperature. The temperature measuring means 12 for tubular body is electrically connected to a tubular body temperature controller 26 that is disposed outside the vacuum chamber 1. The tubular body temperature controller 26 is connected to the power supply 21 for tubular body heater. By this configuration, based on the temperature measured by the temperature measuring means 12 for tubular body, the heat amount of the tubular body heater 36 can be varied by control of the electric power fed to it, and the temperature of the tubular body 3 can be adjusted.

The bottom 3c of the tubular body 3 includes a plurality of bottom holes 3b, and an evaporation section 2 is engaged and mounted in each bottom hole 3b. The upper surface of the evaporation section 2 includes an evaporation section opening 2a, and the evaporation section opening 2a is disposed at the same level as that of the bottom 3c.

In the example of FIG. 1, two evaporation sections 2 and 2 including a first evaporation section 2x and second evaporation section 2y are disposed. However, two or more evaporation sections may be disposed. Here, the number of evaporation sections 2 is the same as the number of bottom holes 3b.

An evaporation section heater 35 is built in each evaporation section 2. Each evaporation section 2 can be heated by heating each evaporation section heater 35 by power fed from each power supply 20 for evaporation section heater that is connected to the evaporation section heater 35. Here, one power supply 20 for evaporation section heater is disposed for each evaporation section 2, and all power supplies 20 are disposed outside the vacuum chamber 1.

Each evaporation section 2 includes a temperature measuring means 11 for evaporation section such as a thermocouple capable of measuring a temperature. Each temperature measuring means 11 for evaporation section is electrically connected to each evaporation section temperature controller 25 that is disposed outside the vacuum chamber 1. Each evaporation section temperature controller 25 is connected to each power supply 20 for evaporation section heater. One evaporation section temperature controller 25 and one power supply 20 for evaporation section heater are disposed for each evaporation section 2. By this configuration, based on the temperature measured by the temperature measuring means 11 for evaporation section, the heat amount of each evaporation section heater 35 can be varied by control of the electric power fed to it, and the temperature of each evaporation section 2 can be adjusted.

A deposition material 9 is stored in each evaporation section 2. The deposition material 9 may be stored in a separately formed heating container such as a crucible.

The deposition material 9 may be made of any material, for example an organic material for forming organic electroluminescence. In the embodiment of FIG. 1, two evaporation sections 2 including a first evaporation section 2x and second evaporation section 2y are disposed. In this case, the same or different deposition materials 9x and 9y may be stored in the first evaporation section 2x and second evaporation section 2y, respectively. When different deposition materials 9 are stored in a plurality of evaporation sections 2, respectively, the deposition materials 9 can be co-deposited, and a co-deposition film is produced on the deposition target 4.

The film thickness meters 10 (10x and 10y) used in the vacuum deposition device A of the present invention are not especially limited as long as they can measure the thickness of the deposition film. For example, a quartz oscillator type film thickness meter may be used. The quartz oscillator type film thickness meter can automatically measure the thickness of the deposition film that is adhesively deposited on a surface of a quartz oscillator. In the present invention, a plurality of film thickness meters 10 (film thickness meters 10x and 10y in FIG. 1) are disposed. Each film thickness meter 10 is electrically connected to a deposition rate controller 24 that is disposed outside the vacuum chamber 1. The deposition rate controller 24 is connected to all power supplies 20 for evaporation section heater. By this configuration, when the deposition rate is intended to be varied during deposition based on the film thickness value measured by the film thickness meter 10, the deposition rate can be adjusted by varying the electric power fed from power supplies 20 for evaporation section heater.

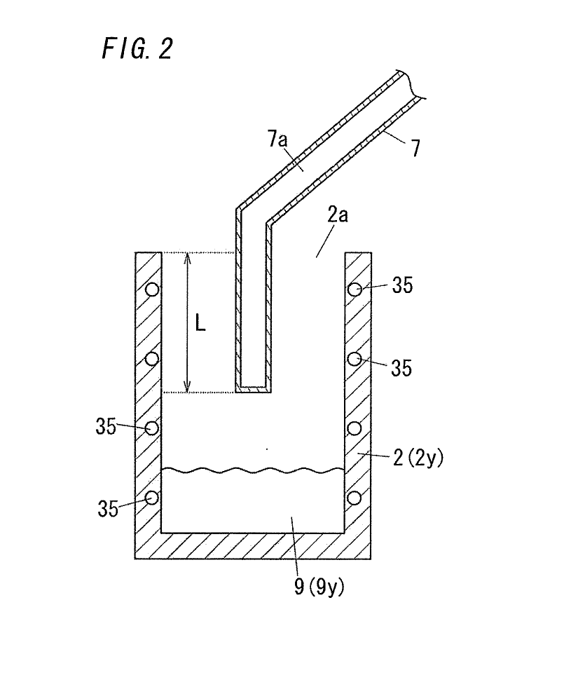

The vacuum deposition device A of the present invention includes a guide tube 7. The guide tube 7 includes a space as a ventilation channel 7a inside it and includes openings at both ends thereof. As shown in FIG. 1, the guide tube 7 may be disposed so that its one opening end (lower side) is positioned at substantially the same level (or, just the same level) as that of the opening surface (namely, evaporation section opening 2a) of the evaporation section 2 (2y). Alternatively, as shown in FIG. 2, the guide tube 7 may be disposed so that the one opening end is positioned inside the evaporation section 2 (2y). The inside of the evaporation section 2 means the space between the evaporation section opening 2a and the bottom of the evaporation section 2. Especially, when the deposition material 9 is stored in the evaporation section 2, the inside of the evaporation section 2 means the space between the deposition material 9 and the evaporation section opening 2a.

When one opening end of the guide tube 7 is disposed inside the evaporation section 2 as shown in FIG. 2, preferably, the length of a part of the guide tube 7 inside the evaporation section 2 is two or more times the square root of the area of the evaporation section opening 2a (opening surface of the evaporation section 2). In other words, when the one opening end of the guide tube 7 is extended into the evaporation section 2, preferably, the relation L≧2×√A (√A denotes the square root of A) is satisfied. Here, A (unit is mm², for example) shows the area of the evaporation section opening 2a, and L (unit is mm, for example) shows the length of the part of the guide tube 7 inside the evaporation section 2. In this case, as shown in the simulation result described later, deposition materials 9 other than the deposition material 9 whose film thickness is to be measured is easily inhibited from adhering to the film thickness meter 10 during the deposition of the deposition material 9, and the measurement accuracy of the thickness of the deposition film can be improved. The area A does not include the area of the edge of the evaporation section 2.

The other opening end (upper side) of the guide tube 7 is guided out of the tubular body 3 through a through hole 3d that is formed in a side wall surface of the tubular body 3, and is extended to a proximity of the film thickness meter 10 (10y) that is disposed outside the tubular body 3. The opening end on the upper side of the guide tube 7 may be in contact with the film thickness meter 10y. When the opening end on the upper side of the guide tube 7 and the film thickness meter 10y are not in contact with each other, preferably, the distance between them is 300 mm or less.

As discussed above, by providing the guide tube 7, the deposition material 9 (9y) vaporized from the evaporation section 2 (2y) travels from the one opening end of the guide tube 7 into the ventilation channel 7a inside the guide tube 7, passes through the ventilation channel 7a, travels out of the other opening end of the guide tube 7, and arrives at the film thickness meter 10y.

In the embodiments of FIG. 1 and FIG. 2, the guide tube 7 extends from the film thickness meter 10 side to the evaporation section opening 2a, and is bent above the evaporation section opening 2a such that it substantially drops to the evaporation section opening 2a. The present invention is not limited to this. In other words, in the embodiment of FIG. 2, the guide tube 7 substantially drops to the evaporation section opening 2a and extends into the evaporation section 2. However, the guide tube 7 may extend into the evaporation section 2 so that the guide tube 7 enters the opening surface of the evaporation section 2 at an acute angle. In this case, preferably, the opening surface of the opening end of the guide tube 7 that exists in the evaporation section 2 is formed so as to be parallel to the evaporation section opening 2a. In FIG. 2, the film thickness meter 10 and the tubular body 3 are not shown.

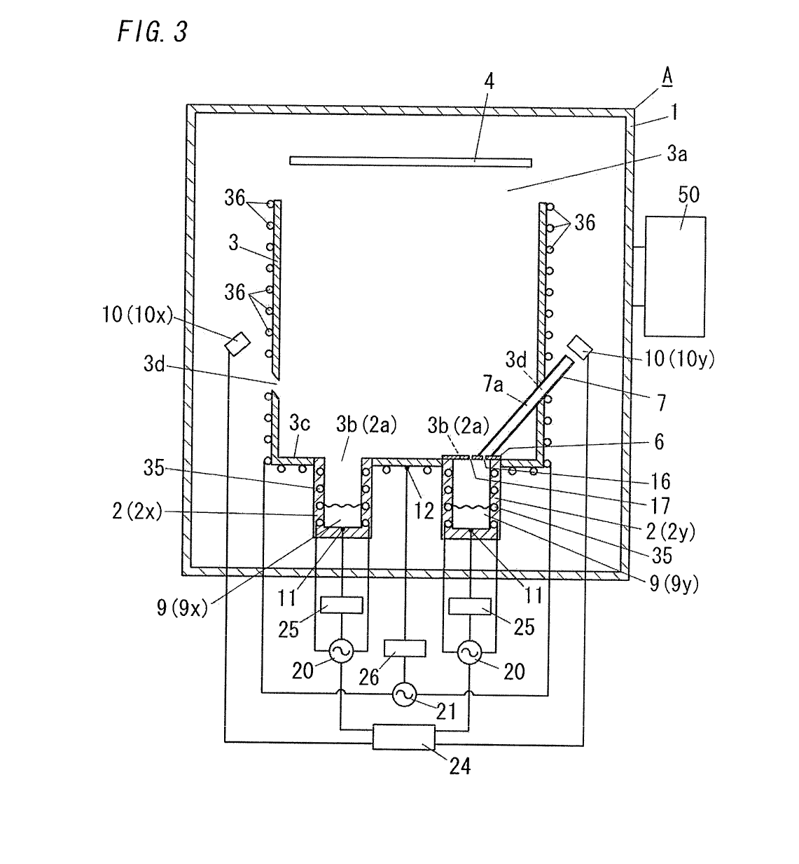

In the vacuum deposition device A of the present invention, a lid body 6 may be disposed on the guide tube 7 as shown in the embodiment of FIG. 3. In this embodiment, the guide tube 7 and lid body 6 are disposed for the second evaporation section 2y. Conversely, the guide tube 7 and lid body 6 may be disposed for the first evaporation section 2x. Alternatively, the guide tube 7 and lid body 6 may be disposed for both the evaporation sections 2. Hereinafter, the case where the guide tube 7 and lid body 6 are disposed for the second evaporation section 2y is described as an example.

The lid body 6 is formed in a plate shape, can be positioned on the upper surface of the evaporation section opening 2a, and blocks the evaporation section opening. Furthermore, the lid body 6 includes two holes: an orifice 17 for deposition and an orifice 16 for film thickness measurement. When the lid body 6 is disposed on the evaporation section 2 as discussed above, the orifice 17 for deposition and the orifice 16 for film thickness measurement are positioned at substantially the same level as that of the opening surface of the evaporation section 2.

The orifice 17 for deposition is a hole for guiding, into the tubular body 3, the deposition material 9y vaporized from the evaporation section 2y having the lid body 6. The shape of the orifice 17 for deposition is not especially limited. For example, the shape may be a circuit, and the diameter thereof is preferably 0.5 to 50 mm. The number of orifices 17 for deposition formed in the lid body 6 may be only one, or two or more.

The orifice 16 for film thickness measurement is a hole for guiding the deposition material 9y vaporized from the evaporation section 2y having the lid body 6 to the film thickness meter 10y that is disposed outside the tubular body 3. The shape of the orifice 16 for film thickness measurement is not especially limited. For example, the shape may be a circuit, and the diameter thereof is preferably 0.5 to 50 mm.

When the lid body 6 is disposed as discussed above, the guide tube 7 is disposed between the orifice 16 for film thickness measurement and the film thickness meter 10 as shown in FIG. 3, and one opening end (opening surface) of the guide tube 7 can be disposed at substantially the same level as that of the orifice 16 for film thickness measurement or disposed so as to block the orifice 16 for film thickness measurement. The other configurations are the same as those described in the embodiments of FIG. 1 and FIG. 2.

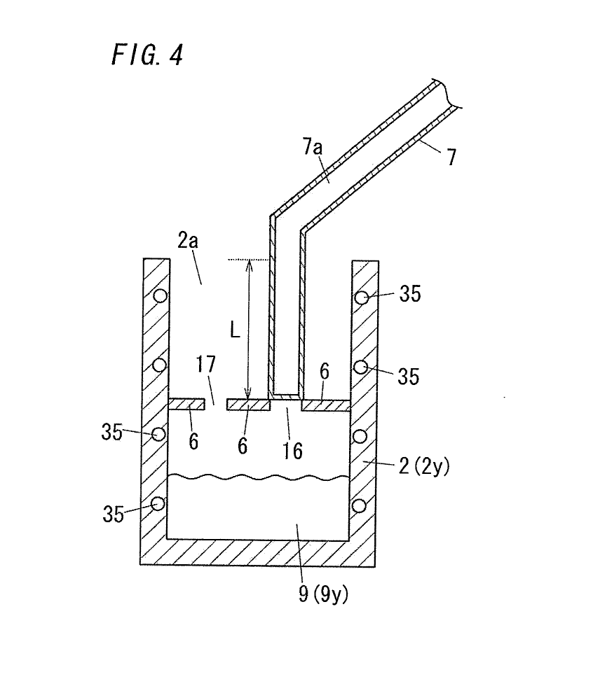

The lid body 6 may be positioned inside the evaporation section 2 as shown in FIG. 4. Also in this embodiment, the opening end (opening surface) of the guide tube 7 is disposed at substantially the same level as that of the orifice 16 for film thickness measurement or disposed so as to block the orifice 16 for film thickness measurement. Preferably, the outer edge of the lid body 6 is fixed to the inner wall surface of the evaporation section 2. Also in this embodiment, preferably, the length of a part of the guide tube 7 inside the evaporation section 2 is two or more times the square root of the area of the evaporation section opening 2a (opening surface of the evaporation section 2) (L≧2×√A).

Furthermore, preferably, the diameter of the cross section of the guide tube 7 is larger than the diameter of the orifice 16 for film thickness measurement. In this case, the deposition material 9y having passed through the orifice 16 for film thickness measurement can be inhibited from leaking out of the guide tube 7, the error of film thickness measurement can be reduced to increase the measurement accuracy.

By the embodiments of FIG. 3 and FIG. 4, especially, deposition materials 9 other than the deposition material 9 whose film thickness is to be measured is easily inhibited from adhering to the film thickness meter 10, and the measurement accuracy of the thickness of the deposition film can be further improved.

Next, a method of depositing a deposition material 9 to a deposition target 4 in the vacuum deposition device A of the present invention is described. In this description, as shown in FIG. 3, the vacuum deposition device A includes two evaporation sections 2, namely a first evaporation section 2x and second evaporation section 2y. A lid body 6 is disposed for the second evaporation section 2y, and two deposition materials 9x and 9y are co-deposited.

First, each deposition material 9 is stored in each heating container disposed in each evaporation section 2. For example, the first deposition material 9x may be stored in the first evaporation section 2x and the second deposition material 9y may be stored in the second evaporation section 2y, and vice versa. Next, the vacuum pump 50 is operated to decompress the inside of the vacuum chamber 1 into the vacuum state.

Then, by power fed from the power supply 20 for evaporation section heater and the power supply 21 for tubular body heater, the evaporation section heater 35 and tubular body heater 36 are heated, and each evaporation section 2 and the tubular body 3 are heated. At this time, the tubular body 3 is heated at a temperature at which all deposition materials 9, namely both the first deposition material 9x and the second deposition material 9y, are vaporized and are not decomposed. By such heating, each deposition material 9 is gradually evaporated through sublimation or melting, and thus the vaporization of each deposition material 9 starts.

The first deposition material 9x vaporized from the first evaporation section 2x that includes no lid body 6 travels directly toward the tubular body opening 3a, or travels toward it while being reflected on the inner wall surface of the tubular body 3. Finally, the first deposition material 9x arrives at and adheres to the lower surface of the deposition target 4, and is deposited on the deposition target 4 to produce a deposition film. The tubular body 3 is heated at the temperature at which the deposition materials 9x and 9y are vaporized, so that the deposition materials 9x and 9y can be inhibited from adhering to the inner wall surface of the tubular body 3.

While, the second deposition material 9y vaporized from the second evaporation section 2y that includes the lid body 6 passes through one of the orifice 17 for deposition and orifice 16 for film thickness measurement which are disposed in the lid body 6. The deposition material 9y having passed through the orifice 17 for deposition comes into the tubular body 3, and a deposition film is produced on the deposition target 4 similarly to the above description. The deposition material 9y having passed through the orifice 16 for film thickness measurement comes into the ventilation channel 7a of the guide tube 7, passes through the ventilation channel 7a, arrives at the film thickness meter 10y, and is deposited on the film thickness meter 10y.

Also in the vacuum deposition devices A of the embodiments of FIG. 1 and FIG. 2 including no lid body 6, the deposition material 9 vaporized from the evaporation section 2 comes into the tubular body 3 and the ventilation channel 7a of the guide tube 7. Then, a deposition film is produced on the deposition target 4, and a deposition film is also produced on the film thickness meter 10 through the guide tube 7.

There is a relationship between the thickness of the deposition film produced on the film thickness meter 10y and that of the deposition film produced on the deposition target 4, so that the thickness of the deposition film produced on the deposition target 4 can be indirectly detected based on the thickness value measured by the film thickness meter 10y. Therefore, when the thickness of the deposition film per unit time is measured by the film thickness meter 10y, a deposition rate is calculated. The deposition rate can be therefore varied based on the measurement result of the film thickness. In order to vary the deposition rate, the electric power to be supplied to the temperature measuring means 11 for evaporation section is adjusted.

In the vacuum deposition device A of the present invention, the guide tube 7 is disposed between one evaporation section 2 (2y) and one film thickness meter 10 (10y), so that the deposition material 9 (9x) vaporized from the other evaporation section 2 (2x) is inhibited from adhering to the film thickness meter 10y. Thus, the deposition material 9 (9x) stored in the other evaporation section 2 (2x), which is not a measuring object, is inhibited from adhering to the film thickness meter 10 (10y). The thickness of the deposition material 9 (9y) vaporized from the evaporation section 2 (2y) can be therefore more accurately measured. Therefore, feedback control to the evaporation section heater 35 based on the measurement result of the film thickness meter 10y can be more accurately performed, and fluctuation in deposition rate can be inhibited. Thus, the measurement accuracy by the film thickness meter 10y is improved, so that the thickness of the deposition film produced on the deposition target 4 can be more accurately controlled.

Furthermore, a deposition film more than a necessary amount is inhibited from adhering to the film thickness meter 10y. For example, when a quartz oscillator type film thickness meter is used as the film thickness meter 10y, reduction and deviation of the oscillating frequency or oscillating strength of the quartz oscillator can be minimized. Therefore, the lifetime of the quartz oscillator can be extended, advantageously. The adhesion amount of the deposition material 9y to the film thickness meter 10y can be finely adjusted, so that an effort to appropriately adjust the positional relationship between the evaporation section and the film thickness meter in response to the deposition rate to finely adjust the adhesion amount can be omitted.

Especially, when the lid body 6 is disposed in the evaporation section 2 and the orifice 16 for film thickness measurement is connected to the film thickness meter 10 through guide tube 7, the deposition material 9 vaporized from the other evaporation section 2 can be further inhibited from adhering to the film thickness meter 10. Therefore, comparing with the vacuum deposition device A including no lid body 6, the vaporized deposition material 9 can be more accurately guided to the film thickness meter 10 and deposition target 4, adhesion to an undesired place is reduced, and hence the above-mentioned effect becomes remarkable.

Next, another embodiment of the vacuum deposition device A of the present invention is described. For example, the orifice 17 for deposition may include an opening area controlling means 15. By the opening area controlling means 15, the opening area of the orifice 17 for deposition can be optionally adjusted, and the flow rate of the deposition material 9 vaporized from the evaporation section 2 can be controlled.

As the opening area controlling means 15, for example, a throttle mechanism 111 can be employed as shown in FIG. 5. The throttle mechanism 111 includes a disk-like member 61 and a plurality of throttle blade members 62 of a substantially parallelogrammatic shape. The disk-like member 61 is formed in the so-called doughnut shape having a circular cavity 61a in its center part. The diameter of the cavity 61a in the disk-like member 61 is substantially equal to that of the orifice 17 for deposition, and the cavity 61a and the orifice 17 for deposition overlap each other. The throttle blade members 62 surround the outer periphery of the disk-like member 61, and are partially positioned below the disk-like member 61. Adjacent throttle blade members 62 are disposed so that ends of them overlap each other.

The throttle blade members 62 are attached on the lid body 6 by inserting a support pin 60 into one corner of each throttle blade member 62, and each throttle blade member 62 is rotatable about the support pin 60.

The throttle blade members 62 can be rotated in response to an electric signal from the outside. Specifically, each throttle blade member 62 rotates about the support pin 60 along the upper surface of the lid body 6 toward the orifice 17 for deposition. Each throttle blade member 62 may rotate clockwise or counterclockwise, but preferably rotates so as to take the shortest distance (in the arrow direction in FIG. 5). All of the throttle blade members 62 simultaneously start rotating, and rotate by the same angle. Thus, the rotation of the throttle blade members 62 allows the opening of the orifice 17 for deposition to be gradually reduced and blocked from the outer periphery. Adjustment of the rotation angle of the throttle blade members 62 allows adjustment of the opening area of the orifice 17 for deposition. The throttle mechanism 111 can return the rotated throttle blade members 62 to the original positions, and can open or close the opening of the orifice 17 for deposition.

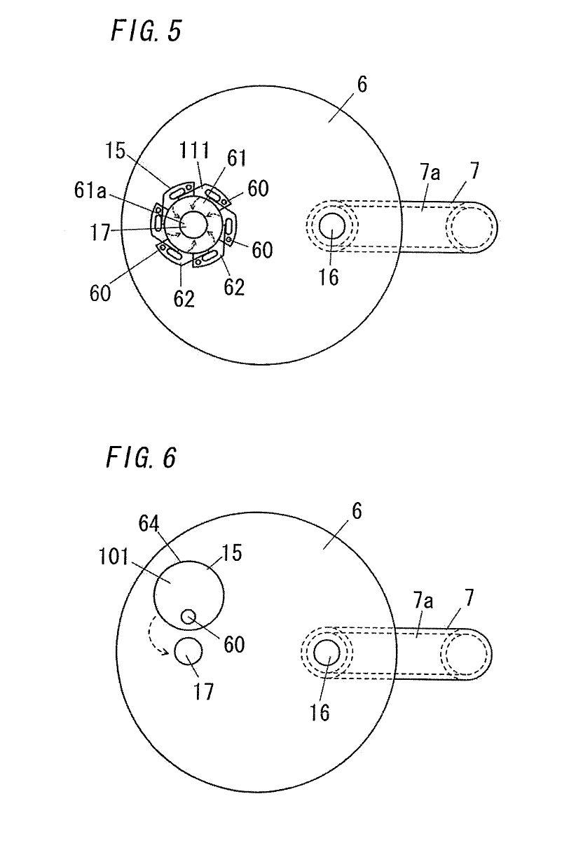

As the opening area controlling means 15, for example, a rotating mechanism 101 may be employed as shown in FIG. 6. The rotating mechanism 101 is formed of a flat plate member 64, and is disposed on the lid body 6 near the orifice 17 for deposition. The plate member 64 has a disk shape, but the present invention is not limited to this. The plate member 64 may have another shape such as an ellipse, rectangle, or triangle. The plate member 64 is set larger than the opening of the orifice 17 for deposition.

The plate member 64 is attached on the lid body 6 by inserting a support pin 60 to penetrate the plate member 64 from the surface. The plate member 64 can rotate about the support pin 60 along the upper surface of the lid body 6 (e.g. in the arrow direction in FIG. 6) in response to an electric signal from the outside. The rotation direction may be clockwise or counterclockwise.

The rotation of the plate member 64 allows the opening of the orifice 17 for deposition to be partially blocked, and the opening area is adjusted in response to the blocking degree. The plate member 64 can be returned to the original position, so that the opening of the orifice 17 for deposition can be opened or closed.

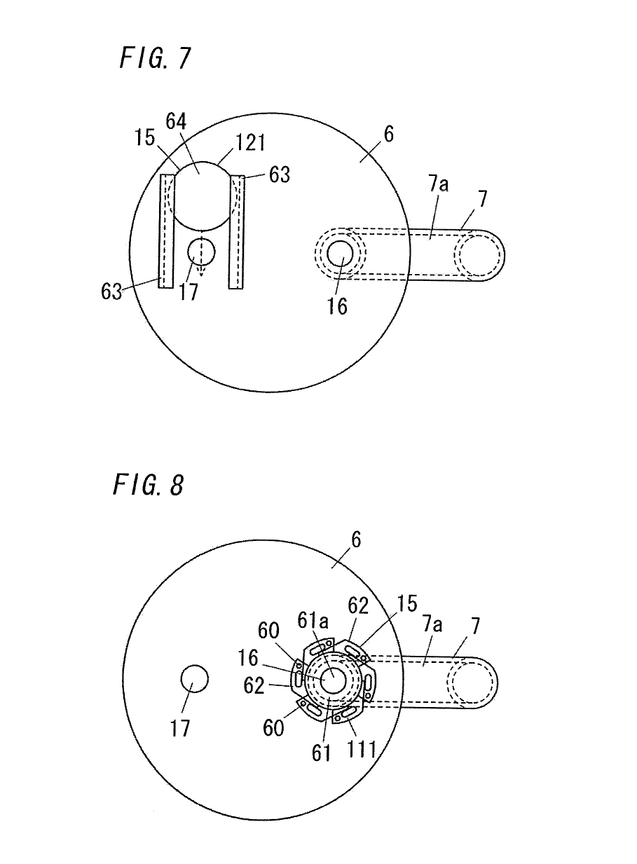

As another opening area controlling means 15, for example, a sliding mechanism 121 may be employed as shown in FIG. 7. Similarly to the above description, the plate member 64 for adjusting the opening area of the orifice 17 for deposition is held by a pair of rail members 63, and can slide from one end side of the pair of rail members 63 to the other end side. The pair of rail members 63 are disposed in parallel so that the orifice 17 for deposition is sandwiched between them.

When the plate member 64 slides along the rail members 63 in response to an electric signal sent from the outside, the opening of the orifice 17 for deposition is partially blocked, and the opening area is adjusted in response to the blocking degree. Since the plate member 64 can reciprocate between the ends of the pair of rail members 63, the sliding mechanism 121 can open or close the opening of the orifice 17 for deposition.

The vacuum deposition device A of the present invention may include various opening area controlling means 15 discussed above, so that an effort to separately form a plurality of lid bodies 6 for different opening areas of the orifice 17 for deposition can be omitted.

Furthermore, all opening area controlling means 15 can control the opening area of the orifice 17 for deposition to a desired value. Therefore, when the deposition rate of the deposition material 9 vaporized from the evaporation section 2 is intended to be varied, the deposition rate can be easily varied by varying the opening area. The opening area can be adjusted also during co-deposition, so that the deposition rate can be varied by adjusting the opening area even during deposition.

In the vacuum deposition device A of the present invention, the opening area controlling means 15 can be disposed also in the orifice 16 for film thickness measurement. Also in this case, by the opening area controlling means 15, the opening area of the orifice 16 for film thickness measurement can be optionally adjusted, and the flow rate of the deposition material 9 vaporized from the evaporation section 2 can be controlled.

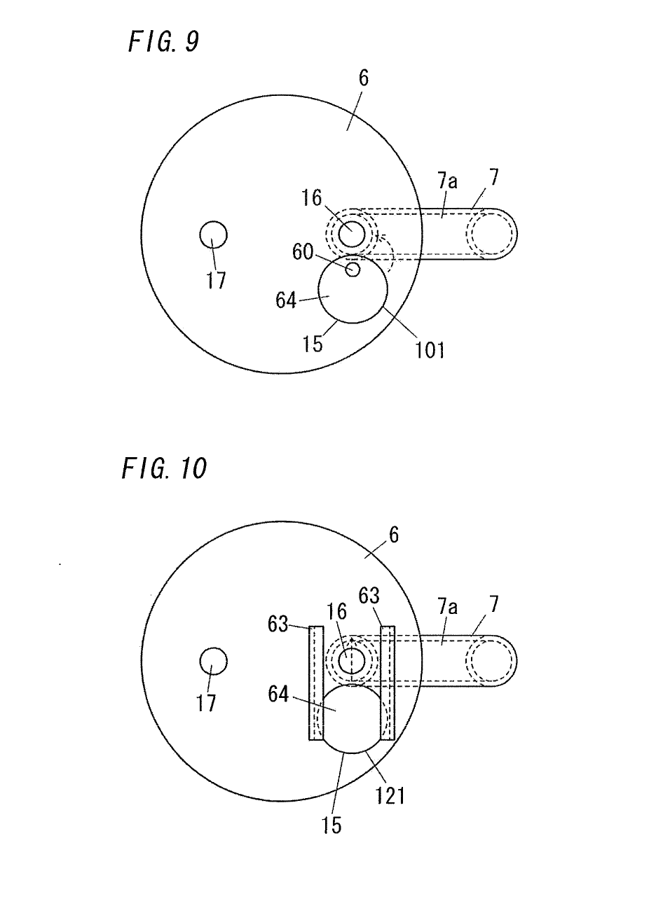

As the opening area controlling means 15 to be disposed in the orifice 16 for film thickness measurement, as shown in FIG. 8 to FIG. 10, one of the throttle mechanism 111, rotating mechanism 101, and sliding mechanism 121 that have configurations similar to the above-mentioned configurations can be employed. The blade members 62 of the throttle mechanism 111, and the plate members 64 of the rotating mechanism 101 and sliding mechanism 121 adjust the opening area of the orifice 16 for film thickness measurement between the opening of the guide tube 7 on the orifice 16 side and the orifice 16 for film thickness measurement. The blade members 62 of the throttle mechanism 111 disposed in the orifice 16 for film thickness measurement and rotating mechanism 101 operate similarly to those disposed in the orifice 17 for deposition.

When the opening area controlling means 15 is disposed also in the orifice 16 for film thickness measurement, the opening area of the orifice 16 for film thickness measurement can be easily adjusted, and the flow rate and deposition rate of the deposition material 9 arriving at the film thickness meter 10 can be controlled.

The opening area controlling means 15 may be disposed in only one of the orifice 17 for deposition and orifice 16 for film thickness measurement, or may be in both of them. When the opening area controlling means 15 is disposed in both of the orifice 17 for deposition and orifice 16 for film thickness measurement, the orifice 17 and orifice 16 are opened or closed independently.

FIG. 8 shows an example of another embodiment of the vacuum deposition device A of the present invention. In this embodiment, the vacuum deposition device A of the present invention may include, also in the lid body 6 and the guide tube 7, a heating mechanism 40 such as a heater and a temperature adjusting mechanism 41 for adjusting the temperature of the heating mechanism 40.

A lid body heater 37 is employed as the heating mechanism 40 disposed in the lid body 6, and is attached on the surface of the lid body 6. The lid body heater 37 is connected to a power supply 22 for lid body heater that is disposed outside the vacuum chamber. The lid body heater 37 generates heat by power fed from the power supply 22 for lid body heater, and thus heats the lid body 6.

As the temperature adjusting mechanism 41 for adjusting the temperature of the heating mechanism 40 such as the lid body heater 37, a lid body temperature controller 27 and a temperature measuring means 13 for lid body connected to the controller 27 can be employed. The temperature measuring means 13 for lid body can be disposed on the surface of the lid body 6. As, the temperature measuring means 13, for example, a thermocouple capable of measuring a temperature can be employed. The temperature measuring means 13 for lid body is electrically connected to the lid body temperature controller 27 that is disposed outside the vacuum chamber 1. The lid body temperature controller 27 is connected to the power supply 22 for lid body heater. By this configuration, based on the temperature measured by the temperature measuring means 13 for lid body, the heat amount of the lid body heater 37 can be varied by control of the electric power fed to it, and the temperature of the lid body 6 can be adjusted.

A guide tube heater 38 is employed as the heating mechanism 40 disposed in the guide tube 7, and is attached on the outer periphery of the guide tube 7. The guide tube heater 38 is connected to a power supply 23 for guide tube heater that is disposed outside the vacuum chamber. The guide tube heater 38 generates heat by power fed from the power supply 23 for guide tube heater, and thus heats the guide tube 7.

The heating mechanism 40 disposed in the guide tube 7 also includes a temperature adjusting mechanism 41 for adjusting the temperature of the heating mechanism 40. Specifically, a guide tube temperature controller 28 and a temperature measuring means 14 for guide tube connected to the controller 28 can be employed. The temperature measuring means 14 for guide tube can be disposed on the surface of the guide tube 7. As the temperature measuring means 14 for guide tube, for example, a thermocouple capable of measuring a temperature can be employed. The temperature measuring means 14 for guide tube is electrically connected to the guide tube temperature controller 28 that is disposed outside the vacuum chamber 1. By this configuration, based on the temperature measured by the temperature measuring means 14 for guide tube, the heat amount of the guide tube heater 38 can be varied by control of the electric power fed to it, and the temperature of the guide tube 7 can be adjusted.

In the present embodiment, the heating mechanism 40 and temperature adjusting mechanism 41 may be disposed in any one of the lid body 6 and guide tube 7, or may be disposed in both of them.

Since the heating mechanism 40 and temperature adjusting mechanism 41 are disposed in the lid body 6 or guide tube 7, the deposition material 9 can be inhibited from adhering to the lid body 6 or guide tube 7. Therefore, the possibility of varying the conductance of the orifice 17 for deposition and orifice 16 for film thickness measurement is reduced, the deposition rate becomes stable, and the thickness of the deposition film can be further strictly controlled. Conventionally, the deposition material 9 is apt to adhere to the lid body 6 or guide tube 7 and the deposition rate is often difficult to be controlled, dependently on the material and shape of the lid body 6 or guide tube 7. In the present invention, due to the above-mentioned configuration, the material and shape of the lid body 6 or guide tube 7 can be made to hardly affect this control.

In the present invention, the vacuum deposition device A may include no lid body 6, or may include, in the guide tube 7, a heating mechanism 40 and temperature adjusting mechanism 41 similar to those described above.

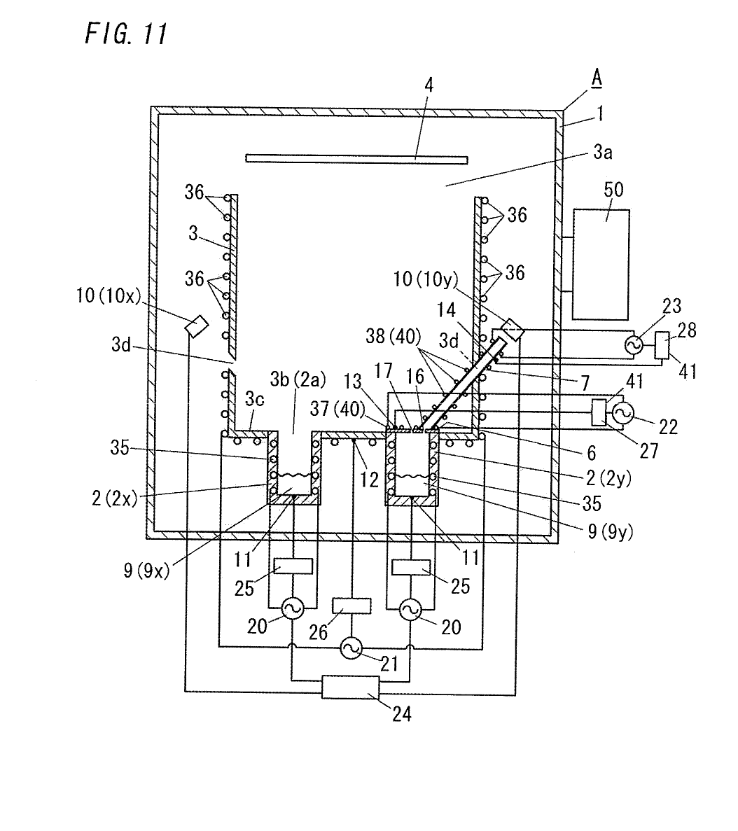

In the vacuum deposition device A of the present invention, the lid body 6 is disposed in the second evaporation section 2y in the embodiments of FIG. 3 and FIG. 11. However, the lid body 6 may be disposed in the first evaporation section 2x. In this case, the film thickness meter 10x for measuring the thickness of the deposition film of the deposition material 9 vaporized from the first evaporation section 2x is disposed separately. The film thickness meter 10x can be connected, through the guide tube 7, to the orifice 16 for film thickness measurement of the lid body 6 disposed in the first evaporation section 2x, as discussed above. For this purpose, a through hole 3d for passing the guide tube 7 is disposed separately in the side wall surface of the tubular body 3. In the vacuum deposition device A of the present invention, the lid body 6 and guide tube 7 may be simultaneously attached on both of the first evaporation section 2x and second evaporation section 2y.

Thus, the film thickness meters 10 are disposed correspondingly to the evaporation sections 2. For example, the film thickness meter 10x is disposed for the evaporation section 2x and the film thickness meter 10y is disposed for the evaporation section 2y. Therefore, the thickness of the deposition film of the deposition material 9 vaporized from each evaporation section 2 can be measured.

(Simulation verification by the vacuum deposition device A) A simulation of the deposition rate and thickness of the deposition film produced using the vacuum deposition device A of the present invention is described hereinafter. Specifically, the deposition rate from the evaporation section 2 when tris(8-hydroxyquinolinate) aluminum complex (Alq3) is deposited as the deposition material 9 is calculated using a direct simulation Monte Carlo method. In the simulation calculation, a calculation condition is set based on the molecular weight, molecular size, and evaporation temperature of Alq3.

In the vacuum deposition device A used for the simulation, the tubular body 3 has a rectangular square-cylinder shape, the width of the inner wall is 200 mm, the depth is 100 mm, the height is 200 mm, and the heating temperature of the tubular body 3 is 300° C. Two evaporation sections 2, namely the first evaporation section 2x and second evaporation section 2y, are disposed. Alq3 is stored in each of the evaporation sections 2. Each of the first evaporation section 2x and second evaporation section 2y has a cylindrical shape and includes an evaporation section opening 2a with a diameter of 30 mm. At this time, the area A of the evaporation section opening 2a is 706.5 mm², and the value of 2√A is about 53.2 mm.

The centers of the evaporation section openings 2a of the first evaporation section 2x and second evaporation section 2y are positioned at a distance of 65 mm in the opposite directions (right and left) by 180° from the center of the bottom 3b of the tubular body 3.

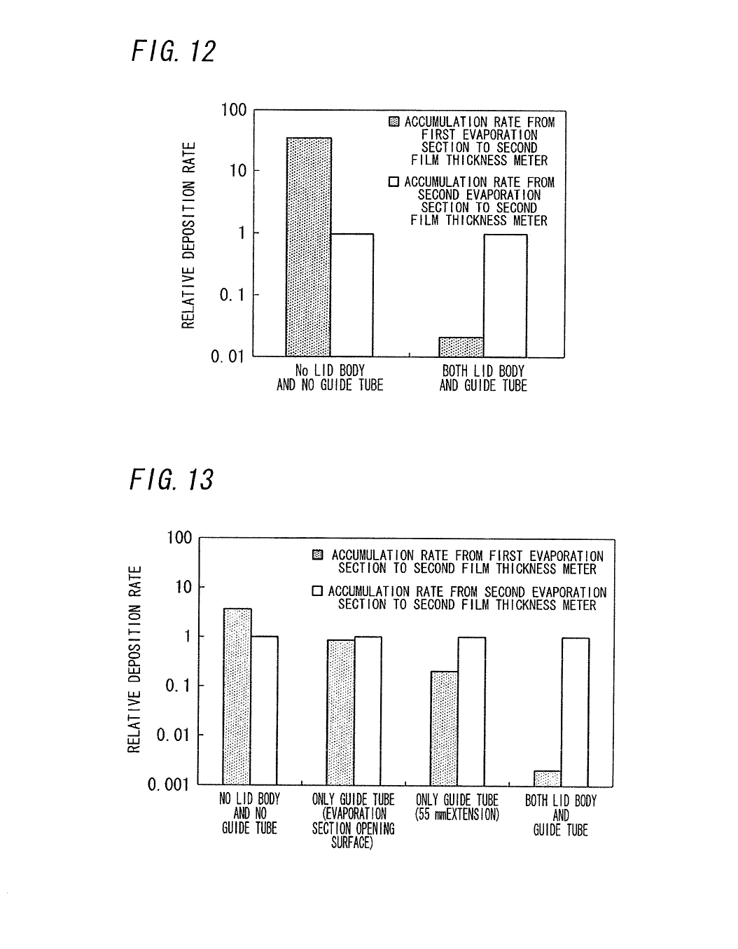

First, the simulation when the lid body 6 and guide tube 7 are neither attached to the first evaporation section 2x nor the second evaporation section 2y is performed as reference. The simulation is performed under two conditions where the ratio of the deposition rate from the first evaporation section 2x to the deposition target 4 to that from the second evaporation section 2y to the deposition target 4 is 1:0.01 and 1:0.1. FIG. 12 shows the simulation result when the ratio between the deposition rates is 1:0.01. FIG. 13 and Table 1 show the simulation result when the ratio between the deposition rates is 1:0.1.

The simulation (no lid body 6 and no guide tube 7) has the following result shown in FIG. 12:

the deposition material 9x vaporized from the first evaporation section 2x arrives at the second film thickness meter 10y at a deposition rate that is 30 or more times the deposition rate of the deposition material 9y vaporized from the second evaporation section 2y.

In FIG. 13 and Table 1, when the ratio between the deposition rates is 1:0.1, the deposition material 9x travels at a deposition rate that is about 3.5 times the deposition rate of the deposition material 9y. FIG. 12 and FIG. 13 show the relative deposition rate when the deposition rate of the deposition material 9y from the second evaporation section 2y to the second film thickness meter 10y is set at 1.

The simulation is similarly performed in the following cases:

only the guide tube 7 is disposed in the second evaporation section 2y, and the opening surface of the guide tube 7 on the evaporation section 2 side is disposed at the same level as that of the opening surface of the evaporation section 2;

only the guide tube 7 is disposed in the second evaporation section 2y, and the opening surface of the guide tube 7 on the evaporation section 2 side is extended into the evaporation section 2 by 55 mm; and

both the lid body 6 and the guide tube 7 are disposed in the second evaporation section 2y, and the lid body 6 is disposed at the same level as that of the evaporation section openings 2a.

In the case where the opening surface of the guide tube 7 on the evaporation section 2 side is extended into the evaporation section 2 by 55 mm, the extension direction of the guide tube 7 into the evaporation section 2 is substantially orthogonal to the opening surface of the evaporation section 2. The length of 55 mm is longer than the value of 2√A (53.2 mm).

The lid body 6 has a circular orifice 17 for deposition with a diameter of 2 mm and a circular orifice 16 for film thickness measurement with a diameter of 2 mm. The opening surface of one end of the guide tube 7 faces the orifice 16 for film thickness measurement, and forms an angle of 60° with respect to the surface of the lid body 6 (or evaporation section opening 2a). The other end of the guide tube 7 is extended to a proximity of the second film thickness meter 10y through the through hole 3d formed in the side wall surface of the tubular body 3.

Similarly, evaluation is performed under two conditions where the ratio of the deposition rate from the first evaporation section 2 to the deposition target 4 to that from the second evaporation section 2 to the deposition target 4 is 1:0.01 and 1:0.1. FIG. 12 shows the simulation result when the ratio between the deposition rates is 1:0.01. FIG. 13 and Table 1 show the simulation result when the ratio between the deposition rates is 1:0.1.

First, the case where the ratio between the deposition rates is 1:0.01 is described in detail. According to the result of the ratio between deposition rates shown in FIG. 12, the deposition material 9x vaporized from the first evaporation section 2x is inhibited from adhering to the second film thickness meter 10y. Here, the deposition rate of the deposition material 9y from the second evaporation section 2y to the second film thickness meter 10y is assumed to be 1. Specifically, the adhesion amount of the deposition material 9x vaporized from the first evaporation section 2x to the second film thickness meter 10y is about 2% of the adhesion amount of the deposition material 9y, and is suppressed to 1/1000 or less of that in the case where no lid body 6 and no guide tube 7 is disposed. In the vacuum deposition device A having the configuration of FIG. 3, the guide tube 7 and lid body 6 are disposed between the second evaporation section 2 and the second film thickness meter 10y. Therefore, the adhesion of the deposition material 9x vaporized from the first evaporation section 2x to the second film thickness meter 10y is significantly suppressed. As a result, the influence on the measured film thickness of the deposition film of the deposition material 9y vaporized from the second evaporation section 2y is small, and the deposition rate of the deposition material 9y vaporized from the second evaporation section 2y can be more accurately adjusted.

As shown in FIG. 13 and Table 1, also in the case where the ratio between the deposition rates is 1:0.1, the deposition rate of the deposition material 9x from the first evaporation section 2x to the second film thickness meter 10y is lower when only the guide tube 7 is disposed or both of the lid body 6 and the guide tube 7 are disposed than when no lid body 6 and no guide tube 7 is disposed. Specifically, when the opening surface of the guide tube 7 is disposed at the same level as that of the evaporation section opening 2a (in FIG. 13 and Table 1, “evaporation section opening surface” is described), the deposition rate of the deposition material 9x to the second film thickness meter 10y is about 80% of that of the deposition material 9y. The feedback control of the deposition rate of the deposition material 9y is easier than that when no lid body 6 and no guide tube 7 is disposed. When the opening surface of the guide tube 7 is extended by 55 mm beyond the evaporation section opening 2a (in FIG. 13 and Table 1, “55 mm extension” is described), the deposition rate of the deposition material 9x to the second film thickness meter 10y is about 20% of the deposition rate of the deposition material 9y. It is indicated that the feedback control of the deposition rate of the deposition material 9y is easier. When both of the lid body 6 and the guide tube 7 are disposed, the adhesion amount of the deposition material 9x vaporized from the first evaporation section 2x to the second film thickness meter 10y is about 0.2% of the adhesion amount of the deposition material 9y, namely is suppressed significantly. It is indicated that the feedback control of the deposition rate of the deposition material 9y is especially easy.

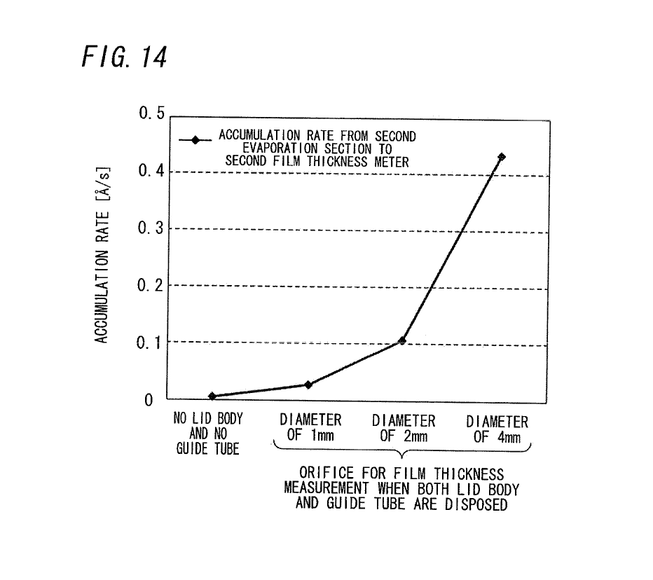

Here, it is assumed that the deposition rate of the deposition material from the second evaporation section 2y to deposition target 4 is 0.01 Å/s. In this case, as shown in FIG. 14, the deposition rate of the deposition material 9y from the second evaporation section 2y to the second film thickness meter 10y when no lid body 6 and no guide tube 7 is disposed is 0.004 Å/s. In other words, it is indicated that the adhesion amount of the deposition material 9y from the second evaporation section 2y to the second film thickness meter 10y is small.

When both of the lid body 6 and the guide tube 7 are disposed and the diameter of the orifice 16 for film thickness measurement is varied, the deposition rate varies with the diameter. For example, when the diameter of the orifice 16 for film thickness measurement is 2 mm, the deposition rate of the deposition material 9y from the second evaporation section 2y to the second film thickness meter 10y is about 25 times that when no lid body 6 and no guide tube 7 is disposed. Thus, it is indicated that the influence of the adhesion of the deposition material 9x is small when both of the lid body 6 and the guide tube 7 are disposed.

When it is assumed that an appropriate deposition rate for performing stable control for a long time is about 0.1 Å/s, the diameter of the orifice 16 for film thickness measurement is preferably set at 2 mm according to FIG. 14. Thus, in the vacuum deposition device A of the present invention, the deposition rate of the deposition film can be adjusted to a desired value solely by appropriately adjusting the diameter of the orifice 16 for film thickness measurement.

TABLE 1

| | Relative deposition rate of deposition |
|---|---|
| | material from first evaporation section to |
| | second film thickness meter when |
| | deposition rate of deposition material from |
| Configuration of vacuum | second evaporation section to second |
| deposition device | film thicknes smeter is set at 1 |
| No guide tube and no lid body | 3.5 |
| Only guide tube, evaporation | 0.79 |
| section opening surface | |
| Only guide tube, 55 mm | 0.20 |
| extension | |
| Both guide tube and lid body | 0.002 |

### REFERENCE SIGNS LIST

A Vacuum deposition device
1 Vacuum chamber
2 Evaporation section
2a Evaporation section opening
3 Tubular body
4 Deposition target
6 Lid body
7 Guide tube
7a Ventilation channel
9 Deposition material
10 Deposition film
13 Temperature measuring means for lid body
14 Temperature measuring means for guide tube
15 Opening area controlling means
16 Orifice for film thickness measurement
17 Orifice for deposition
40 Heating mechanism
41 Temperature adjusting mechanism

1. A vacuum deposition device comprising, in a vacuum chamber:
a plurality of evaporation sections;
a deposition target;
a tubular body surrounding a space between the plurality of evaporation sections and the deposition target; and
a film thickness meter,
wherein
a deposition material vaporized from the plurality of evaporation sections passes through the tubular body, reaches a surface of the deposition target, and is deposited on the surface,
a guide tube is disposed between the film thickness meter and at least one of the plurality of evaporation sections, the guide tube guiding the deposition material vaporized from the evaporation section to the film thickness meter, and
an opening surface of the guide tube on the evaporation section side is disposed at substantially the same level as that of an opening surface of the evaporation section or inside the evaporation section.

2. The vacuum deposition device according to claim 1, wherein
the guide tube is extended to the inside of the evaporation section, and the length of a part of the guide tube is two or more times the square root of an area of the opening surface of the evaporation section, the part existing inside the evaporation section.

3. The vacuum deposition device according to claim 1, wherein
at least one of the plurality of evaporation sections includes a lid body, the lid body being disposed at substantially the same level as that of the opening surface of the evaporation section or inside the evaporation section so as to block an opening of the evaporation section,
the lid body includes:
an orifice for deposition for guiding, into the tubular body, the deposition material vaporized from the evaporation section having the lid body; and
an orifice for film thickness measurement for guiding, to the film thickness meter, the deposition material vaporized from the evaporation section having the lid body, and
the guide tube is disposed between the film thickness meter and the orifice for film thickness measurement.

4. The vacuum deposition device according to claim 3, further comprising an opening area controlling means on the lid body, the opening area controlling means allowing an opening area of the orifice for deposition to be adjusted.

5. The vacuum deposition device according to claim 3, further comprising an opening area controlling means on the lid body, the opening area controlling means allowing an opening area of the orifice for film thickness measurement to be adjusted.

6. The vacuum deposition device according to claim 3, further comprising:
a heating mechanism in at least one of the lid body and the guide tube; and
a temperature adjusting mechanism for controlling the heating mechanism.

7. The vacuum deposition device according to claim 2, wherein
at least one of the plurality of evaporation sections includes a lid body, the lid body being disposed at substantially the same level as that of the opening surface of the evaporation section or inside the evaporation section so as to block an opening of the evaporation section,
the lid body includes:
an orifice for deposition for guiding, into the tubular body, the deposition material vaporized from the evaporation section having the lid body; and
an orifice for film thickness measurement for guiding, to the film thickness meter, the deposition material vaporized from the evaporation section having the lid body, and
the guide tube is disposed between the film thickness meter and the orifice for film thickness measurement.

8. The vacuum deposition device according to claim 7, further comprising an opening area controlling means on the lid body, the opening area controlling means allowing an opening area of the orifice for deposition to be adjusted.

9. The vacuum deposition device according to claim 7, further comprising an opening area controlling means on the lid body, the opening area controlling means allowing an opening area of the orifice for film thickness measurement to be adjusted.

10. The vacuum deposition device according to claim 4, further comprising an opening area controlling means on the lid body, the opening area controlling means allowing an opening area of the orifice for film thickness measurement to be adjusted.

11. The vacuum deposition device according to claim 8, further comprising an opening area controlling means on the lid body, the opening area controlling means allowing an opening area of the orifice for film thickness measurement to be adjusted.

12. The vacuum deposition device according to claim 7, further comprising:
a heating mechanism in at least one of the lid body and the guide tube; and
a temperature adjusting mechanism for controlling the heating mechanism.

13. The vacuum deposition device according to claim 4, further comprising:
a heating mechanism in at least one of the lid body and the guide tube; and
a temperature adjusting mechanism for controlling the heating mechanism.

14. The vacuum deposition device according to claim 8, further comprising:
a heating mechanism in at least one of the lid body and the guide tube; and
a temperature adjusting mechanism for controlling the heating mechanism.

15. The vacuum deposition device according to claim 5, further comprising:
a heating mechanism in at least one of the lid body and the guide tube; and
a temperature adjusting mechanism for controlling the heating mechanism.

16. The vacuum deposition device according to claim 9, further comprising:
a heating mechanism in at least one of the lid body and the guide tube; and
a temperature adjusting mechanism for controlling the heating mechanism.

17. The vacuum deposition device according to claim 10, further comprising:
a heating mechanism in at least one of the lid body and the guide tube; and
a temperature adjusting mechanism for controlling the heating mechanism.

18. The vacuum deposition device according to claim 11, further comprising:
a heating mechanism in at least one of the lid body and the guide tube; and
a temperature adjusting mechanism for controlling the heating mechanism.
